(19) United States
(12) Patent Application Publication
(10) Pub. No.: US 2024/0222455 A1
(43) Pub. Date: Jul. 4, 2024

(54) HIGH-VOLTAGE TRANSISTOR, LEVEL-UP SHIFTING CIRCUIT, AND SEMICONDUCTOR DEVICE

(71) Applicant: UNITED MICROELECTRONICS CORP., Hsin-Chu City (TW)

(72) Inventors: Wei-Hsuan Chang, Tainan City (TW); Ming-Hua Tsai, Tainan City (TW); Chin-Chia Kuo, Tainan City (TW)

(73) Assignee: UNITED MICROELECTRONICS CORP., Hsin-Chu City (TW)

(21) Appl. No.: 18/107,516

(22) Filed: Feb. 9, 2023

(30) Foreign Application Priority Data
Dec. 28, 2022 (TW) 111150397

(51) Int. Cl. H01L 29/423; H01L 27/088; H01L 29/10; H01L 29/78

(52) U.S. Cl. CPC H01L 29/42368; H01L 27/088; H01L 29/1066; H01L 29/7816; H01L 29/41725

(57) ABSTRACT

A high-voltage transistor includes a well region disposed in a semiconductor substrate, a gate structure disposed above the well region, a gate oxide layer disposed between the gate structure and the well region, a first drift region, and a second drift region. A first portion of the gate oxide layer is thicker than a second portion of the gate oxide layer. A thickness of the second portion is greater than or equal to one eighth of a thickness of the first portion. The first drift region and the second drift region are disposed in the well region, at least partially located at two opposite sides of the gate structure, respectively, and disposed adjacent to the first portion and the second portion, respectively. A conductivity type of the first drift region is identical to that of the second drift region. A level-up shifting circuit includes the high-voltage transistor described above.

### BACKGROUND OF THE INVENTION

### 1. Field of the Invention

The present invention relates to a transistor, a level-up shifting circuit, and a semiconductor device, and more particularly, to a transistor including a gate oxide layer having different thicknesses at different portions, a level-up shifting circuit including this transistor, and a semiconductor device including this transistor.

### 2. Description of the Prior Art

Double-diffused MOS (DMOS) transistor devices have drawn much attention in power devices having high voltage capability. The conventional DMOS transistor devices are categorized into vertical double-diffused MOS (VDMOS) transistor device and lateral double-diffused MOS (LDMOS) transistor device. Having advantage of higher operational bandwidth, higher operational efficiency, and convenience to be integrated with other integrated circuit due to its planar structure, LDMOS transistor devices are prevalently used in high operation voltage environment such as CPU power supply, power management system, AC/DC converter, high-power or high frequency band power amplifier, and level shifting circuit.

### SUMMARY OF THE INVENTION

A high-voltage transistor, a level-up shifting circuit, and a semiconductor device are provided in the present invention. A gate oxide layer having different thicknesses at different portions is used to lower the threshold voltage of the high-voltage transistor, and high voltage may still be applied to the gate structure for satisfying operation requirements of specific circuits by controlling the thickness ratio relationship between different portions of the gate oxide layer.

According to an embodiment of the present invention, a high-voltage transistor is provided. The high-voltage transistor includes a well region, a gate structure, a gate oxide layer, a first drift region, and a second drift region. The well region is disposed in a semiconductor substrate, the gate structure is disposed above the well region, and the gate oxide layer is disposed between the gate structure and the well region in a vertical direction. A first portion of the gate oxide layer is thicker than a second portion of the gate oxide layer, and a thickness of the second portion is greater than or equal to one eighth of a thickness of the first portion. The first drift region and the second drift region are disposed in the well region, and at least a part of the first drift region and at least a part of the second drift region are located at two opposite sides of the gate structure in a horizontal direction, respectively. The first drift region is disposed adjacent to the first portion of the gate oxide layer, the second drift region is disposed adjacent to the second portion of the gate oxide layer, and a conductivity type of the first drift region is identical to a conductivity type of the second drift region.

According to an embodiment of the present invention, a level-up shifting circuit is provided. The level-up shifting circuit includes a first high-voltage transistor. The first high-voltage transistor includes a first well region, a first gate structure, a first gate oxide layer, a first drift region, and a second drift region. The first well region is disposed in a semiconductor substrate, the first gate structure is disposed above the first well region, and a first gate oxide layer is disposed between the first gate structure and the first well region in a vertical direction. A first portion of the first gate oxide layer is thicker than a second portion of the first gate oxide layer, and a thickness of the second portion is greater than or equal to one eighth of a thickness of the first portion. The first drift region and the second drift region are disposed in the first well region, and at least a part of the first drift region and at least a part of the second drift region are located at two opposite sides of the first gate structure in a horizontal direction, respectively. The first drift region is disposed adjacent to the first portion of the first gate oxide layer, the second drift region is disposed adjacent to the second portion of the first gate oxide layer, and a conductivity type of the first drift region is identical to a conductivity type of the second drift region.

According to an embodiment of the present invention, a semiconductor device is provided. The semiconductor device includes a first transistor and a second transistor. The first transistor includes a first well region, a first gate structure, and a first gate oxide layer. The second transistor includes a second well region, a second gate structure, and a second gate oxide layer. The first well region and the second well region are disposed in a semiconductor substrate, the first gate structure is disposed above the first well region, and the second gate structure is disposed above the second well region. The first gate oxide layer is disposed between the first gate structure and the first well region in a vertical direction, and the first gate oxide layer includes a first portion and a second portion. The first portion has a first thickness, the second portion has a second thickness, and the first thickness is greater than the second thickness. The second gate oxide layer is disposed between the second gate structure and the second well region in the vertical direction. The second gate oxide layer has a third thickness, and the second thickness is greater than the third thickness.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a high-voltage transistor according to a first embodiment of the present invention.

FIG. 2 is a top view schematic drawing illustrating a high-voltage transistor according to an embodiment of the present invention.

FIG. 3 is a schematic drawing illustrating a high-voltage transistor according to a second embodiment of the present invention.

FIG. 4 is a schematic drawing illustrating a high-voltage transistor according to a third embodiment of the present invention.

FIG. 5 is a schematic drawing illustrating a high-voltage transistor according to a fourth embodiment of the present invention.

FIG. 6 is a schematic drawing illustrating a high-voltage transistor according to a fifth embodiment of the present invention.

FIG. 7 is a schematic drawing illustrating a high-voltage transistor according to a sixth embodiment of the present invention.

FIG. 8 is a schematic drawing illustrating a high-voltage transistor according to a seventh embodiment of the present invention.

FIG. 9 is a schematic drawing illustrating a high-voltage transistor according to an eighth embodiment of the present invention.

FIG. 10 is a schematic drawing illustrating a semiconductor device according to an embodiment of the present invention.

FIG. 11 is a schematic drawing illustrating a high-voltage transistor according to a ninth embodiment of the present invention.

FIG. 12 is a schematic equivalent circuit diagram of a level-up shifting circuit according to an embodiment of the present invention.

FIG. 13 is a schematic drawing illustrating a high-voltage transistor according to another embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

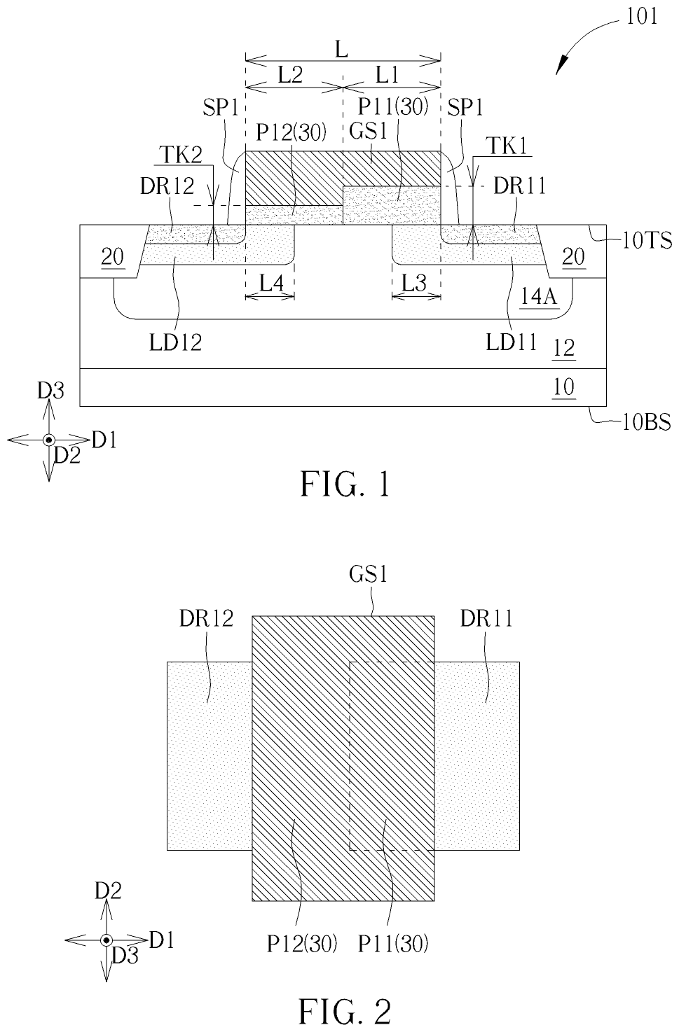

Please refer to FIG. 1. FIG. 1 is a schematic drawing illustrating a high-voltage transistor 101 according to a first embodiment of the present invention. As shown in FIG. 1, the high-voltage transistor 101 includes a well region 14A, a gate structure GS1, a gate oxide layer 30, a first drift region (such as a drift region LD11), and a second drift region (such as a drift region LD12). The well region 14A is disposed in a semiconductor substrate 10, the gate structure GS1 is disposed above the well region 14A, and the gate oxide layer 30 is disposed between the gate structure GS1 and the well region 14A in a vertical direction D3. A first portion P11 of the gate oxide layer 30 is thicker than a second portion P12 of the gate oxide layer 30, and a thickness TK2 of the second portion P12 is greater than or equal to one eighth of a thickness TK1 of the first portion P11. The drift region LD11 and the drift region LD12 are disposed in the well region 14A, and at least a part of the drift region LD11 and at least a part of the drift region LD12 are located at two opposite sides of the gate structure GS1 in a horizontal direction D1, respectively. The drift region LD11 is disposed adjacent to the first portion P11 of the gate oxide layer 30, the drift region LD12 is disposed adjacent to the second portion P12 of the gate oxide layer 30, and a conductivity type of the drift region LD11 is identical to a conductivity type of the drift region LD12. The relatively thin second portion P12 of the gate oxide layer 30 may be used to lower a threshold voltage of the high-voltage transistor 101, and the thickness ratio relationship between the first portion P11 and the second portion P12 of the gate oxide layer 30 may be controlled for avoiding the second portion P12 being too thin. Therefore, high voltage may still be applied to the gate structure GS1 for satisfying operation requirements of specific circuits (such as level shifting circuits, but not limited to this), and the operation performance of the high-voltage transistor 101 and/or related circuits including the high-voltage transistor 101 may be improved accordingly.

In some embodiments, the vertical direction D3 described above may be regarded as a thickness direction of the semiconductor substrate 10. The semiconductor substrate 10 may have a top surface 10TS and a bottom surface 10BS opposite to the top surface 10TS in the vertical direction D3, and the gate structure GS1 described above may be disposed on the side of the top surface 10TS of the semiconductor substrate 10. Horizontal directions substantially orthogonal to the vertical direction D3 (such as the horizontal direction D1, a horizontal direction D2, and other directions orthogonal to the vertical direction D3) may be substantially parallel with the top surface 10TS and/or the bottom surface 10BS of the semiconductor substrate 10, but not limited thereto. In this description, a distance between the bottom surface 10BS of the semiconductor substrate 10 and a relatively higher location and/or a relatively higher part in the vertical direction D3 is greater than a distance between the bottom surface 10BS of the semiconductor substrate 10 and a relatively lower location and/or a relatively lower part in the vertical direction D3. The bottom or lower portion of each component may be closer to the bottom surface 10BS of the semiconductor substrate 10 in the vertical direction D3 than the top or upper portion of this component. Another component disposed above a specific component may be regarded as being relatively far from the bottom surface 10BS of the semiconductor substrate 10 in the vertical direction D3, and another component disposed under a specific component may be regarded as being relatively closer to the bottom surface 10BS of the semiconductor substrate 10 in the vertical direction D3. Additionally, in this description, a top surface of a specific component may include the topmost surface of this component in the vertical direction D3, and a bottom surface of a specific component may include the bottommost surface of this component in the vertical direction D3, but not limited thereto.

In some embodiments, the high-voltage transistor 101 may further include a deep well region 12, an isolation structure 20, a first doped region (such as a doped region DR11), a second doped region (such as a doped region DR12), and a spacer structure SP1. The semiconductor substrate 10 may include a silicon substrate, an epitaxial silicon substrate, a silicon germanium substrate, a silicon carbide substrate, a silicon-on-insulator (SOI) substrate, or a substrate made of other suitable semiconductor materials. The deep well region 12 may be disposed in the semiconductor substrate 10 and located under the well region 14A in the vertical direction D3, and at least a part of the isolation structure 20 may be disposed in the semiconductor substrate 10 for defining a region located corresponding to the high-voltage transistor in the semiconductor substrate 10. The doped region DR11 may be disposed in the drift region LD11, the doped region DR12 may be disposed in the drift region LD12, and the doped region DR11 and the doped region DR12 may be located at two opposite sides of the gate structure GS1 in the horizontal direction D1, respectively. In some embodiments, the doped region DR11 and the doped region DR12 may be source/drain doped regions in the high-voltage transistor 101, and the doped region DR11 and the doped region DR12 may be respectively regarded as at least a portion of a source/drain electrode accordingly. The spacer structure SP1 may be disposed on sidewalls of the gate structure GS1 and sidewalls of the gate oxide layer 30, and the spacer structure SP1 may be located above the doped region DR11 and the doped region DR12 in the vertical direction D3. In some embodiments, the deep well region 12, the well region 14A, the drift region LD11, the drift region LD12, the doped region DR11, and the doped region DR12 may be doped regions formed by performing doping processes (such as implantation processes) to the semiconductor substrate 10. A conductivity type of the doped region DR11 and a conductivity type of the doped region DR12 may be identical to the conductivity type of the drift region LD11 and the conductivity type of the drift region LD12, and the dopant concentration in the doped region DR11 and the doped region DR12 may be higher than the dopant concentration in the drift region LD11 and the drift region LD12. In some embodiments, the drift region LD11 and the drift region LD12 may be formed concurrently by the same process and include substantially the same dopant and/or have substantially the same dopant concentration, and the doped region DR11 and the doped region DR12 may be formed concurrently by the same process and include substantially the same dopant and/or have substantially the same dopant concentration. In addition, the conductivity type of the well region 14A may be complementary to the conductivity type of the doped region DR11, the doped region DR12, the drift region LD11, and the drift region LD12, and the conductivity type of the deep well region 12 may be complementary to or identical to the conductivity type of the well region 14A according to the type of the high-voltage transistor 101. Therefore, the conductivity type of the deep well region 12 may be identical to or complementary to the conductivity type of the doped region DR11, the doped region DR12, the drift region LD11, and the drift region LD12.

For example, when the deep well region 12 is a deep n-type well region and the high-voltage transistor 101 is an n-type transistor, the well region 14A may be a p-type well region, the drift region LD11 and the drift region LD12 may be n-type doped drift regions, and the doped region DR11 and the doped region DR12 may be n-type heavily doped regions. In addition, when the deep well region 12 is a deep n-type well region and the high-voltage transistor 101 is a p-type transistor, the well region 14A may be an n-type well region, the drift region LD11 and the drift region LD12 may be p-type doped drift regions, and the doped region DR11 and the doped region DR12 may be p-type heavily doped regions. In some embodiments, n-type dopants for forming the n-type doped region may include phosphorus (P), arsenic (As), or other suitable n-type doping materials, and p-type dopants for forming the p-type doped region may include boron (B), gallium (Ga), or other suitable p-type doping materials. In addition, a part of the drift region LD11 and a part of the drift region LD12 may be disposed under the gate structure GS1 and the gate oxide layer 30 in the vertical direction D3, and a part of the doped region DR11 and a part of the doped region DR12 may be disposed under the spacer structure SP1 in the vertical direction D3, but not limited thereto. In some embodiments, the drift region LD11 disposed under the gate structure GS1 and the gate oxide layer 30 in the vertical direction D3 may have a length L3 in the horizontal direction D1, which may be less than or equal to a length L1 of the first portion P11 of the gate oxide layer 30 in the horizontal direction D1, and the drift region LD12 disposed under the gate structure GS1 and the gate oxide layer 30 in the vertical direction D3 may have a length L4 in the horizontal direction D1, which may be less than or equal to a length L2 of the second portion P12 of the gate oxide layer 30 in the horizontal direction D1, but not limited thereto.

The gate oxide layer 30 may include silicon oxide or other suitable oxide materials. In some embodiments, a bottom surface of the first portion P11 of the gate oxide layer 30 and a bottom surface of the second portion P12 of the gate oxide layer 30 may be substantially coplanar, a top surface of the first portion P11 may be higher than a top surface of the second portion P12 in the vertical direction D3, and the first portion P11 may be directly connected with the second portion P12, but not limited thereto. For example, two opposite sides of the first portion P11 in the horizontal direction D1 may be directly connected with the spacer structure SP1 and the second portion P12, respectively, and two opposite sides of the second portion P12 in the horizontal direction D1 may be directly connected with the first portion P11 and the spacer structure SP1, respectively. In addition, the relatively thin second portion P12 in the gate oxide layer 30 may be used to lower the threshold voltage, but the second portion P12 cannot be too thin so as to avoid the influence on the ability of the high-voltage transistor 101 to handle high voltage. Therefore, the thickness TK2 of the second portion P12 may be greater than or equal to a quarter of the thickness TK1 of the first portion P11, one-half of the thickness TK1 of the first portion P11, three quarters of the thickness TK1 of the first portion P11, or four fifths of the thickness TK1 of the first portion P11. In other words, the thickness TK2 of the second portion P12 may range from one eighth of the thickness TK1 of the first portion P11 to a quarter of the thickness TK1 of the first portion P11, range from one eighth of the thickness TK1 of the first portion P11 to one-half of the thickness TK1 of the first portion P11, range from one-half of the thickness TK1 of the first portion P11 to three quarters of the thickness TK1 of the first portion P11, range from three quarters of the thickness TK1 of the first portion P11 to four fifths of the thickness TK1 of the first portion P11, or be greater than four fifths of the thickness TK1 of the first portion P11 according to some design considerations. In some embodiments, the thickness TK1 and the thickness TK2 may range from 50 nanometers to 400 nanometers, but not limited thereto. Additionally, the ratio relationship between the first portion P11 and the second portion P12 in the gate oxide layer 30 may be modified according to some design considerations, and the length L1 of the first portion P11 in the horizontal direction D1 may be substantially equal to or different from the length L2 of the second portion P12 in the horizontal direction D1 accordingly. In some embodiments, the length L1 and the length L2 may be equal to each other and may be substantially equal to one-half of a length L of the gate oxide layer 30 and/or the gate structure GS1 in the horizontal direction D1, but not limited thereto.

In some embodiments, the isolation structure 20 may include a single layer or multiple layers of insulation materials, such as oxide insulation materials (such as silicon oxide) or other suitable insulation materials. The spacer structure SP1 may include a single layer or multiple layers of dielectric materials, such as silicon oxide, silicon nitride, silicon oxynitride, or other suitable dielectric materials. The gate structure GS1 may include a gate dielectric layer (not illustrated) and a gate material layer (not illustrated) disposed on the gate dielectric layer. The gate dielectric layer may include high-k dielectric materials or other suitable dielectric materials, and the gate material layer may include a non-metallic electrically conductive material (such as doped polysilicon) or a metallic electrically conductive material, such as a metal gate structure composed of a work function layer and a low resistivity layer stacked thereon, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

Please refer to FIG. 2 and FIG. 1. FIG. 2 is a top view schematic drawing illustrating a high-voltage transistor according to an embodiment of the present invention, wherein some parts (such as the spacer structure and the isolation structure) are not illustrated in FIG. 2. As shown in FIG. 1 and FIG. 2, in some embodiments, the second portion P12 of the gate oxide layer 30 may be partly located at two opposite sides of the first portion P11 in the horizontal direction D2, the horizontal direction D2 may be substantially orthogonal to the horizontal direction D1, and the length L2 of the second portion P12 described above may be regarded as a length of the second portion P12 sandwiched between the spacer structure SP1 and the first portion P11 in the horizontal direction D1. In addition, the design where the second portion P12 in this embodiment is partly located at two opposite sides of the first portion P11 in the horizontal direction D2 may also be applied to other embodiments of the present invention according to some design considerations.

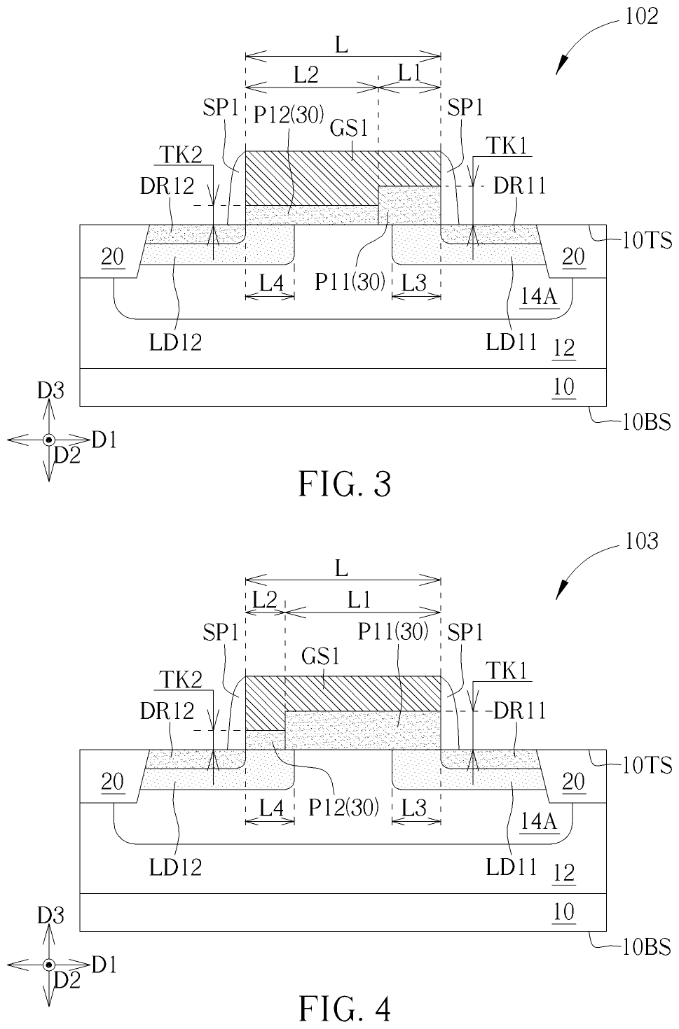

Please refer to FIG. 3 and FIG. 4. FIG. 3 is a schematic drawing illustrating a high-voltage transistor 102 according to a second embodiment of the present invention, and FIG. 4 is a schematic drawing illustrating a high-voltage transistor 103 according to a third embodiment of the present invention. As shown in FIG. 3, in the high-voltage transistor 102, the length L1 of the first portion P11 of the gate oxide layer 30 in the horizontal direction D1 may be less than the length L2 of the second portion P12 of the gate oxide layer 30 in the horizontal direction D1, the length L1 may be less than one-half of the length L of the gate structure GS1 in the horizontal direction D1, and the length L2 may be greater than one-half of the length L. As shown in FIG. 4, in the high-voltage transistor 103, the length L1 of the first portion P11 may be greater than the length L2 of the second portion P12, the length L1 may be greater than one-half of the length L of the gate structure GS1, and the length L2 may be less than one-half of the length L. In some embodiments, in the horizontal direction D1, the length L2 of the second portion P12 may be less than the length L4 of the drift region LD12 disposed under the gate oxide layer 30 in the vertical direction D3, and a part of the drift region LD12 may be disposed under the first portion P11 of the gate oxide layer 30 in the vertical direction D3, but not limited thereto.

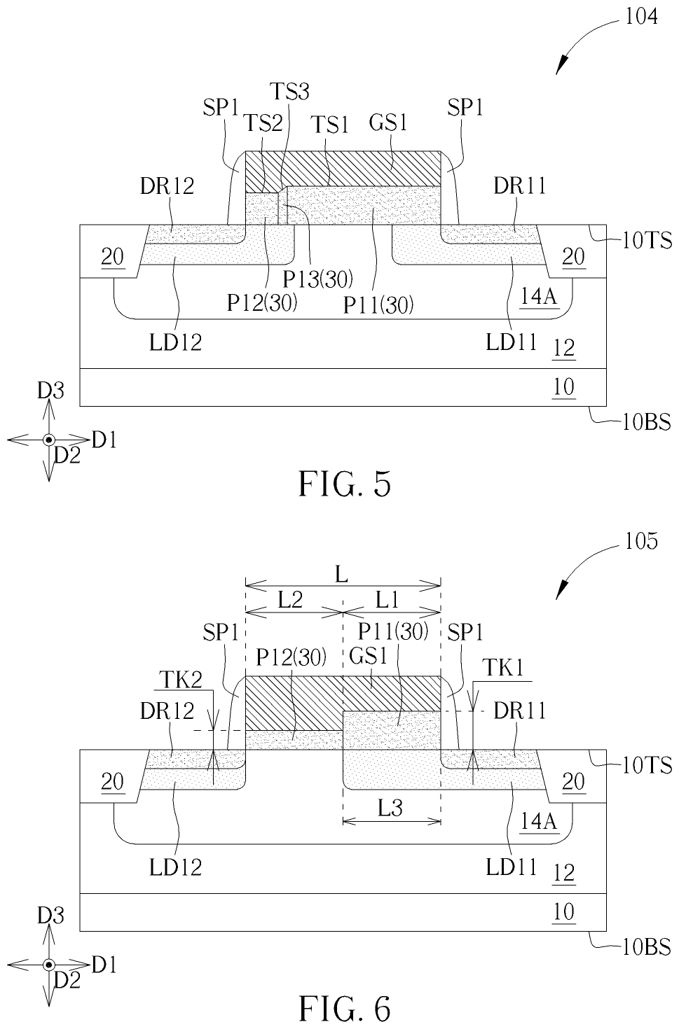

Please refer to FIG. 5. FIG. 5 is a schematic drawing illustrating a high-voltage transistor 104 according to a fourth embodiment of the present invention. As shown in FIG. 5, in the high-voltage transistor 104, the gate oxide layer 30 may further include a third portion P13 disposed between the first portion P11 and the second portion P12, and a top surface TS3 of the third portion P13 may be a sloping surface connected with a top surface TS1 of the first portion P11 and a top surface TS2 of the second portion P12, respectively, and the negative influence of excessive surface undulation of the gate oxide layer 30 on the gate structure GS1 may be improved accordingly. In addition, the third portion P13 in this embodiment may also be applied to other embodiments of the present invention according to some design considerations.

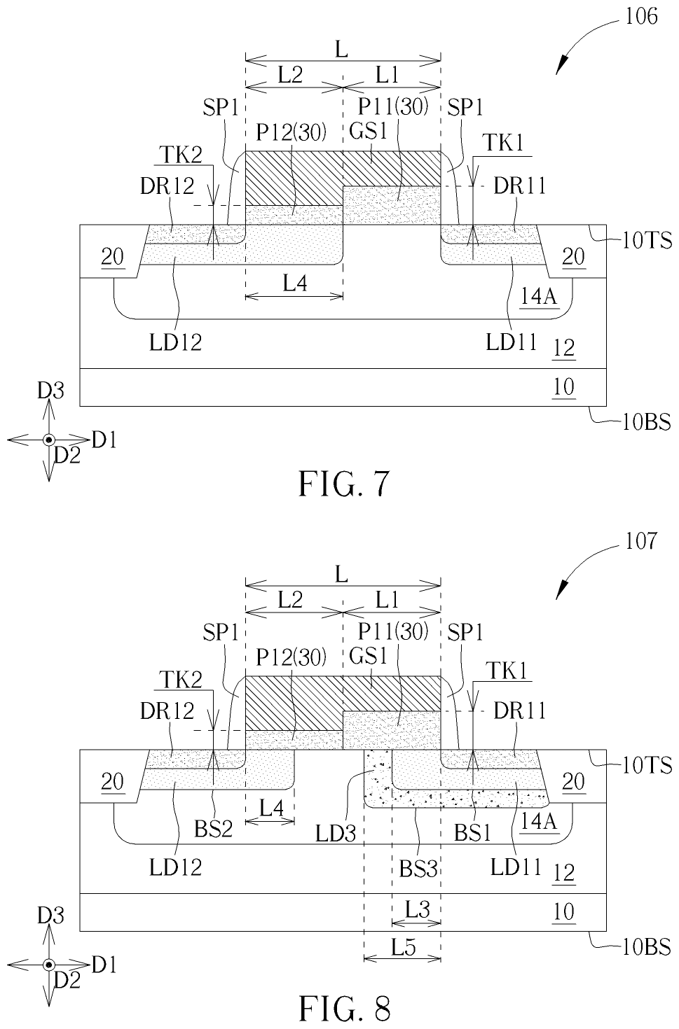

Please refer to FIG. 6 and FIG. 7. FIG. 6 is a schematic drawing illustrating a high-voltage transistor 105 according to a fifth embodiment of the present invention, and FIG. 7 is a schematic drawing illustrating a high-voltage transistor 106 according to a sixth embodiment of the present invention. As shown in FIG. 6, in the high-voltage transistor 105, a part of the drift region LD11 may be disposed under the gate structure GS1 and the gate oxide layer 30 in the vertical direction D3, and the drift region LD12 is not disposed under the gate structure GS1 and the gate oxide layer 30 in the vertical direction D3. In the horizontal direction D1, the length L3 of the drift region LD11 disposed under the gate structure GS1 and the gate oxide layer 30 in the vertical direction D3 may be substantially equal to the length L1 of the first portion P11 of the gate oxide layer 30 in the horizontal direction D1. As shown in FIG. 7, in the high-voltage transistor 106, a part of the drift region LD12 may be disposed under the gate structure GS1 and the gate oxide layer 30 in the vertical direction D3, and the drift region LD11 is not disposed under the gate structure GS1 and the gate oxide layer 30 in the vertical direction D3. In the horizontal direction D1, the length L4 of the drift region LD12 disposed under the gate structure GS1 and the gate oxide layer 30 in the vertical direction D3 may be substantially equal to the length L2 of the second portion P12 of the gate oxide layer 30 in the horizontal direction D1. In other words, the overlapping condition between the drift region LD11 and the gate structure GS1 in the vertical direction D3 and the overlapping condition between the drift region LD12 and the gate structure GS1 in the vertical direction D3 may be further modified according to some design considerations.

Please refer to FIG. 8. FIG. 8 is a schematic drawing illustrating a high-voltage transistor 107 according to a seventh embodiment of the present invention. As shown in FIG. 8, the high-voltage transistor 107 may further include a third drift region (such as a drift region LD3) disposed in the well region 14A and located under the drift region LD11. The drift region LD3 may be used to adjust the range of the drift region located corresponding to the doped region DR11, especially when the drift region LD11 and the drift region LD12 are formed concurrently by the same process, but not limited thereto. Therefore, a conductivity type of the drift region LD3 is identical to the conductivity type of the drift region LD11, and a dopant concentration in the drift region LD3 may be equal to or different from the dopant concentration in the drift region LD11 according to some design considerations. In addition, a bottom (such as a bottom surface BS3) of the drift region LD3 may be lower than a bottom (such as a bottom surface BS2) of the drift region LD12 and a bottom (such as a bottom surface BS1) of the drift region LD11 in the vertical direction D3, and in the horizontal direction D1, a length L5 of the drift region LD3 disposed under the gate structure GS1 and the gate oxide layer 30 in the vertical direction D3 may be greater than the length L3 of the drift region LD11 disposed under the gate structure GS1 and the gate oxide layer 30 in the vertical direction D3. It is worth noting that the drift region LD3 in this embodiment may also be applied to other embodiments of the present invention according to some design considerations.

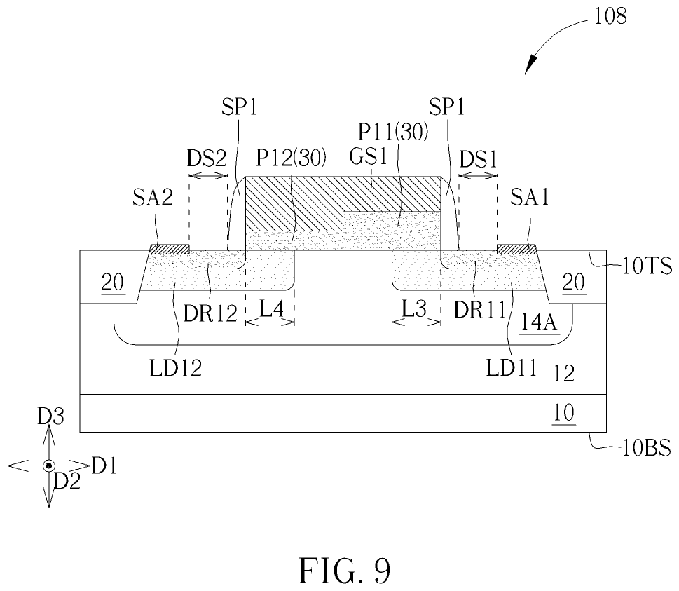

Please refer to FIG. 9. FIG. 9 is a schematic drawing illustrating a high-voltage transistor 108 according to an eighth embodiment of the present invention. As shown in FIG. 9, the high-voltage transistor 108 may further include a silicide layer SA1 and a silicide layer SA2 disposed on the doped region DR11 and the doped region DR12, respectively, and the silicide layer SA1 and the silicide layer SA2 may be separated from the spacer structure SP1 by a distance (such as a distance DS1 and a distance DS2). In other words, the silicide layer SA1 and the silicide layer SA2 may not be directly connected with the spacer structure SP1, and the distance DS1 between the silicide layer SA1 and the spacer structure SP1 and the distance DS2 between the silicide layer SA2 and the spacer structure SP1 may be further modified according to some design considerations for adjusting the electric field distribution during the operation of the high-voltage transistor. Therefore, the distance DS1 may be substantially equal to or different from the distance DS2. In addition, the silicide layer SA1 and the silicide layer SA2 may include metal silicide, such as cobalt-silicide, nickel-silicide, or other suitable metal silicide materials. It is worth noting that the silicide layers in this embodiment may also be applied to other embodiments of the present invention according to some design considerations.

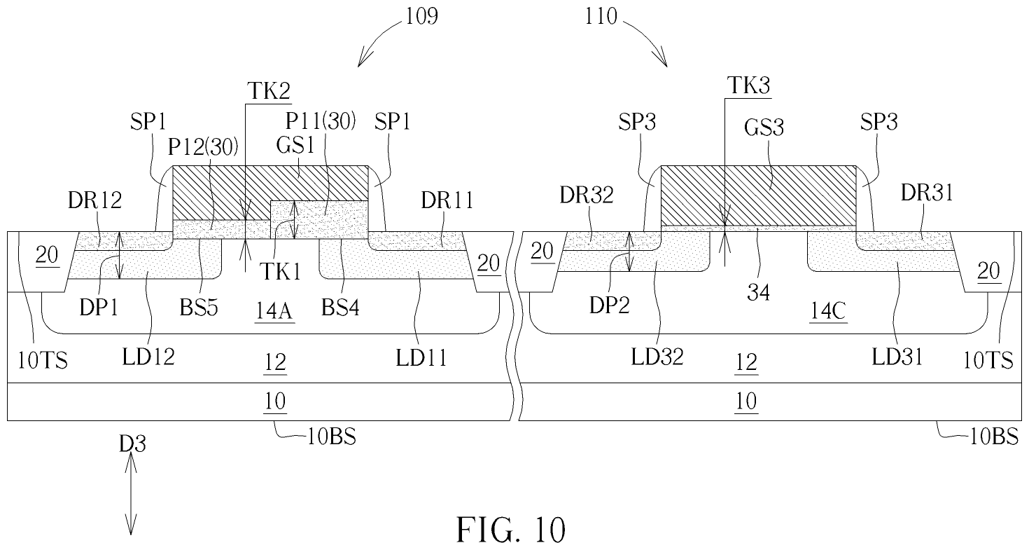

Please refer to FIG. 10. FIG. 10 is a schematic drawing illustrating a semiconductor device according to an embodiment of the present invention. As shown in FIG. 10, the semiconductor device may include a first transistor (such as a transistor 109) and a second transistor (such as a transistor 110). The transistor 109 may include a first well region (such as the well region 14A), a first gate structure (such as the gate structure GS1), and a first gate oxide layer (such as the gate oxide layer 30), and the transistor 110 may include a second well region (such as a well region 14C), a second gate structure (such as a gate structure GS3), and a second gate oxide layer (such as a gate oxide layer 34). The well region 14A and the well region 14C are disposed in the semiconductor substrate 10, the gate structure GS1 is disposed above the well region 14A, and the gate structure GS3 is disposed above the well region 14C. The gate oxide layer 30 is disposed between the gate structure GS1 and the well region 14A in the vertical direction D3, and the gate oxide layer 30 includes the first portion P11 and the second portion P12. The first portion P11 has a first thickness (such as the thickness TK1), the second portion P12 has a second thickness (such as the thickness TK2), and the thickness TK1 is greater than the thickness TK2. The gate oxide layer 34 is disposed between the gate structure GS3 and the well region 14C in the vertical direction D3, the gate oxide layer 34 has a third thickness (such as a thickness TK3), and the thickness TK2 is greater than the thickness TK3.

In some embodiments, the transistor 109 may further include the drift region LD11, the drift region LD12, the doped region DR11, the doped region DR12, and the spacer structure SP1 described above. The drift region LD11 and the drift region LD12 are disposed in the well region 14A, and at least a part of the drift region LD11 and at least a part of the drift region LD12 are disposed at two opposite sides of the gate structure GS1 in the horizontal direction, respectively. The doped region DR11 may be disposed in the drift region LD11, the doped region DR12 may be disposed in the drift region LD12, and the doped region DR11 and the doped region DR12 may be located at two opposite sides of the gate structure GS1 in the horizontal direction, respectively. Additionally, in the transistor 109, at least a part of the gate oxide layer 30 may be disposed in the semiconductor substrate 10, and a bottom surface BS4 of the first portion P11 of the gate oxide layer 30 and a bottom surface BS5 of the second portion P12 of the gate oxide layer 30 may be lower than the top surface 10TS of the semiconductor substrate 10 and/or the top surfaces of the doped region DR11 and the doped region DR12 in the vertical direction D3. Additionally, in some embodiments, the transistor 110 may further include a lightly doped region LD31, a lightly doped region LD32, a doped region DR31, a doped region DR32, and as spacer structure SP3. The lightly doped region LD31 and the lightly doped region LD32 are disposed in the well region 14C and located at two opposite sides of the gate structure GS3, respectively, the doped region DR31 and the doped region DR32 are disposed in the lightly doped region LD31 and the lightly doped region LD32, respectively, and the spacer structure SP3 is disposed on the sidewall of the gate structure GS3. In some embodiments, the spacer structure SP3 may overlap a part of the doped region DR31 and a part of the doped region DR32 in the vertical direction D3 or may not overlap the doped region DR31 and the doped region DR32 in the vertical direction D3 according to some design considerations. In some embodiments, a conductivity type of the lightly doped region LD31, a conductivity type of the lightly doped region LD32, a conductivity type of the doped region DR31, and a conductivity type of the doped region DR32 may be identical to one another, a dopant concentration in the doped region DR31 and the doped region DR32 may be higher than that in the lightly doped region LD31 and the lightly doped region LD32, and a conductivity type of the well region 14C may be complementary to the conductivity type of the lightly doped region LD31, the lightly doped region LD32, the doped region DR31, and the doped region DR32. In addition, a depth of the drift region LD11 and/or the drift region LD12 (such as a depth DP1) may be greater than a depth of the lightly doped region LD31 and/or the lightly doped region LD32 (such as a depth DP2), but not limited thereto. The above-mentioned depth of a specific region may be defined as a distance between the bottommost portion of this region in the vertical direction D3 and the top surface 10TS of the semiconductor substrate 10 in the vertical direction D3.

In some embodiments, a structure the gate structure GS3 may be identical to or different from a structure of the gate structure GS1 and/or a material composition of the gate structure GS3 may be identical to or different from a material composition of the gate structure GS1 according to some design considerations. A structure the spacer structure SP3 may be identical to or different from a structure of the spacer structure SP1 and/or a material composition of the spacer structure SP3 may be identical to or different from a material composition of the spacer structure SP1 according to some design considerations. For example, in some embodiments, both the gate structure GS1 (such as a gate material layer in the gate structure GS1) and the gate structure GS3 (such as agate material layer in the gate structure GS3) may include a metallic electrically conductive material or a non-metallic electrically conductive material. In some embodiments, the gate structure GS1 may include a non-metallic electrically conductive material and the gate structure GS3 may include a metallic electrically conductive material. In some embodiments, the transistor 109 may be a medium-voltage (MV) transistor or a high-voltage transistor, and the transistor may be a low-voltage transistor, but not limited thereto. In addition, the transistor 109 illustrated in FIG. 10 may also be replaced with the high-voltage transistor in other embodiments of the present invention (such as the high-voltage transistors in FIGS. 1 and 3-9 described above, but not limited thereto). In other words, in some embodiments, the semiconductor device may include the transistor 110 and at least one of the high-voltage transistors in FIGS. 1 and 3-9 described above and/or a high-voltage transistor in other embodiment of the present invention.

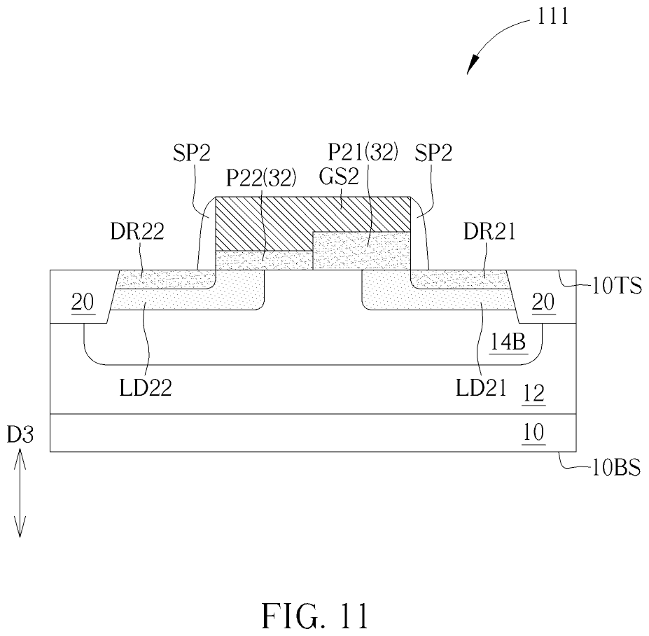

Please refer to FIG. 11 and FIG. 1. FIG. 11 is a schematic drawing illustrating a high-voltage transistor 111 according to a ninth embodiment of the present invention. As shown in FIG. 11, the high-voltage transistor 111 may include a well region 14B, a drift region LD21, a drift region LD22, a doped region DR21, a doped region DR22, a gate structure GS2, a gate oxide layer 32, and a spacer structure SP2. The well region 14B is disposed in the semiconductor substrate 10, the gate structure GS2 is disposed above the well region 14B, and the gate oxide layer 32 is disposed between the gate structure GS2 and the well region 14B in the vertical direction D3. The drift region LD21 and the drift region LD22 are disposed in the well region 14B and located at two opposite sides of the gate structure GS2, respectively, the doped region DR21 and the doped region DR22 are disposed on the drift region LD21 and the drift region LD22, respectively, and the spacer structure SP2 is disposed on the sidewall of the gate structure GS2 and the sidewall of the gate oxide layer 32. A first portion P21 of the gate oxide layer 32 is thicker than a second portion P22 of the gate oxide layer 32, and the thickness of the second portion P22 may be greater than or equal to one eighth of the thickness TK of the first portion P21, a quarter of the thickness of the first portion P21, one-half of the thickness of the first portion P21, three quarters of the thickness of the first portion P21, or four fifths of the thickness of the first portion P21. The drift region LD21 is disposed adjacent to the first portion P21 of the gate oxide layer 32, and the drift region LD22 is disposed adjacent to the second portion P22 of the gate oxide layer 32. A conductivity type of the drift region LD21, a conductivity type of the drift region LD22, a conductivity type of the doped region DR21, and a conductivity type of the doped region DR22 may be identical to one another, and a dopant concentration in the doped region DR21 and the doped region DR22 may be higher than that in the drift region LD21 and the drift region LD22. A conductivity type of the well region 14B may be complementary to the conductivity type of the drift region LD21, the drift region LD22, the doped region DR21, and the doped region DR22, and the conductivity type of the well region 14B may be identical to the conductivity type of the deep well region 12. As shown in FIG. 11 and FIG. 1, in some embodiments, the structures and/or the materials compositions of the gate oxide layer 32, the gate structure GS2, and the spacer structure SP2 may be identical to or similar to the structures and/or the materials compositions of the gate oxide layer 30, the gate structure GS1, and the spacer structure SP1, respectively, but the conductivity type of the well region 14B is complementary to the conductivity type of the well region 14A. The high-voltage transistor 111 and the high-voltage transistor 101 may be different types of high-voltage transistors disposed on the semiconductor substrate 10, such as a p-type high-voltage transistor and an n-type high-voltage transistor, respectively, but not limited thereto.

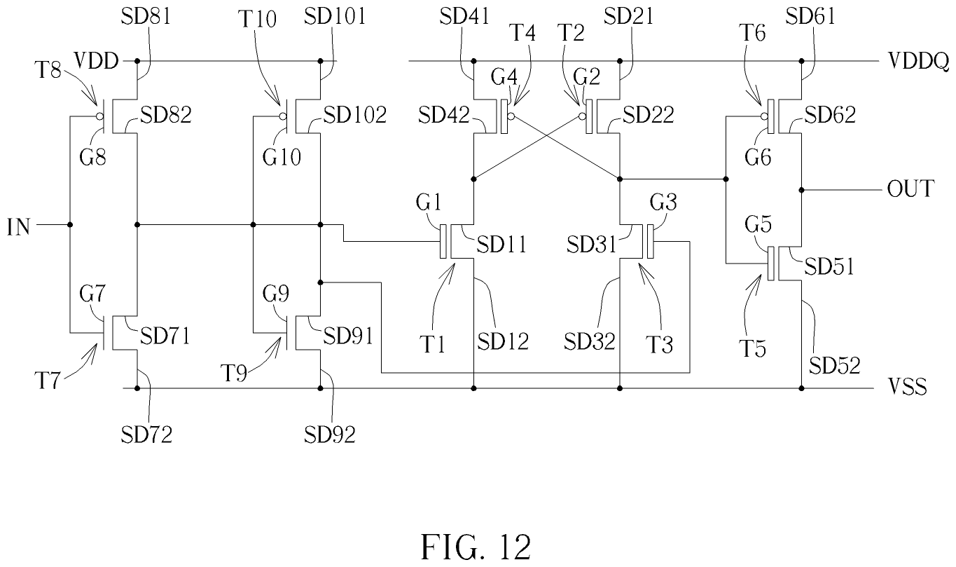

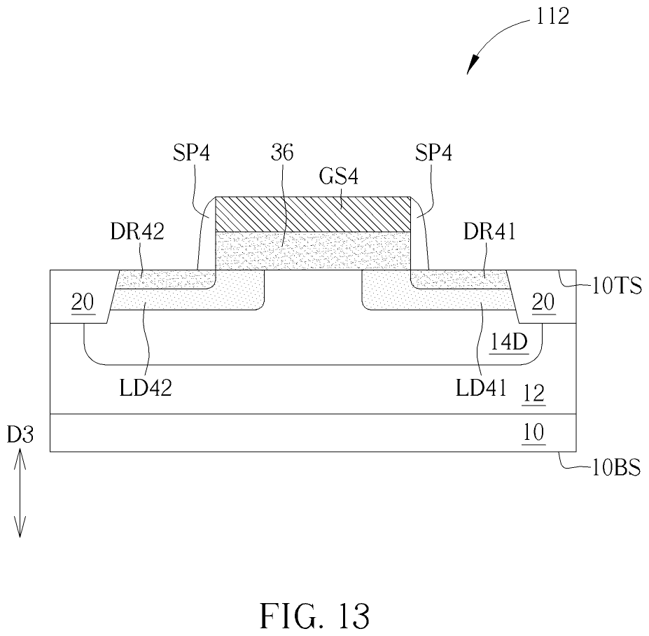

Please refer to FIG. 12, FIG. 13, and FIG. 1. FIG. 12 is a schematic equivalent circuit diagram of a level-up shifting circuit according to an embodiment of the present invention, and FIG. 13 is a schematic drawing illustrating a high-voltage transistor 112 according to another embodiment of the present invention. As shown in FIG. 12, the level-up shifting circuit in this embodiment may include a transistor T1, a transistor T2, a transistor T3, a transistor T4, a transistor T5, a transistor T6, a transistor T7, a transistor T8, a transistor T9, and a transistor T10. In some embodiments, the transistor T1, the transistor T3, the transistor T5, the transistor T7, and the transistor T9 may be n-type transistors, and the transistor T2, the transistor T4, the transistor T6, the transistor T8, and the transistor T10 may be p-type transistors. In addition, the transistor T1, the transistor T3, and the transistor T5 may be n-type high-voltage transistors, and the transistor T2, the transistor T4, and the transistor T6 may be p-type high-voltage transistors. A gate electrode G7 of the transistor T7 and a gate electrode G8 of the transistor T8 may be electrically connected to a first terminal IN, a source/drain electrode SD81 of the transistor T8 and a source/drain electrode SD101 of the transistor T10 may be electrically connected to device voltage VDD, and a source/drain electrode SD12 of the transistor T1, a source/drain electrode SD32 of the transistor T3, a source/drain electrode SD52 of the transistor T5, a source/drain electrode SD72 of the transistor T7, and a source/drain electrode SD92 of the transistor T9 may be electrically connected to reference voltage VSS. A source/drain electrode SD71 of the transistor T7, a source/drain electrode SD82 of the transistor T8, a gate electrode G9 and a source/drain electrode SD91 of the transistor T9, a gate electrode G10 and a source/drain electrode SD102 of the transistor T10, a gate electrode G1 of the transistor T1, and a gate electrode G3 of the transistor T3 may be electrically connected with one another. A gate electrode G2 of the transistor T2, a source/drain electrode SD11 of the transistor T1, and a source/drain electrode SD42 may be electrically connected with one another. A source/drain electrode SD22 of the transistor T2, a source/drain electrode SD31 of the transistor T3, a gate electrode G4 of the transistor T4, a gate electrode G5 of the transistor T5, and a gate electrode G6 of the transistor T6 may be electrically connected to one another. A source/drain electrode SD21 of the transistor T2, a source/drain electrode SD41 of the transistor T4, and a source/drain electrode SD61 of the transistor T6 may be electrically connected to device voltage VDDQ. A source/drain electrode SD51 of the transistor T5 and a source/drain electrode SD62 of the transistor T6 may be electrically connected to a second terminal OUT. In some embodiments, the electric potential of the device voltage VDDQ is higher than the electric potential of the device voltage VDD, and The electric potential of the signal input from the first terminal IN may be raised and output from the second terminal OUT by the level-up shifting circuit in this embodiment.

As shown in FIG. 12 and FIG. 1, in some embodiments, the structures of the transistor T1 and the transistor T3 in the level-up shifting circuit may be identical to that of the high-voltage transistor 101. In other words, two high-voltage transistors 101 may be used as the transistor T1 and the transistor T3 in the level-up shifting circuit, the level-up shifting circuit may be regarded as a circuit including a first high-voltage transistor (such as the high-voltage transistor 101), and the high-voltage transistor 101 may include a first well region (such as the well region 14A), a first gate structure (such as the gate structure GS1), a first gate oxide layer (such as the gate oxide layer 30), a first drift region (such as the drift region LD11), a second drift region (such as the drift region LD12), a first doped region (such as the doped region DR11), and a second doped region (such as the doped region DR12). The well region 14A is disposed in the semiconductor substrate 10, the gate structure GS1 is disposed above the well region 14A, and the gate oxide layer 30 is disposed between the gate structure GS1 and the well region 14A in the vertical direction D3. The first portion P11 of the gate oxide layer 30 is thicker than the second portion P12 of the gate oxide layer 30, and the thickness TK2 of the second portion P12 is greater than or equal to one eighth of the thickness TK1 of the first portion P11. The drift region LD11 and the drift region LD12 are disposed in the well region 14A, and at least a part of the drift region LD11 and at least a part of the drift region LD12 are located at two opposite sides of the gate structure GS1 in the horizontal direction D1, respectively. The drift region LD11 is disposed adjacent to the first portion P11 of the gate oxide layer 30, the drift region LD12 is disposed adjacent to the second portion P12 of the gate oxide layer 30, and the conductivity type of the drift region LD11 is identical to the conductivity type of the drift region LD12. The relatively thin second portion P12 of the gate oxide layer 30 may be used to lower the threshold voltage of the high-voltage transistor 101, the thickness ratio relationship between the first portion P11 and the second portion P12 of the gate oxide layer 30 may be controlled for avoiding the second portion P12 being too thin, and high voltage may still be applied to the gate structure GS1 for high-voltage operation accordingly. The high-voltage transistors 101 may be used as the transistor T1 and the transistor T3 in the level-up shifting circuit for improving the condition that the transistor T1 and the transistor T3 cannot be driven when the device voltage VDD drops, and the operation performance of the level-up shifting circuit may be improved accordingly.

As shown in FIG. 13, the high-voltage transistor 112 may include a well region 14D, a drift region LD41, a drift region LD42, a doped region DR41, a doped region DR42, a gate structure GS4, a gate oxide layer 36, and a spacer structure SP4. The well region 14D is disposed in the semiconductor substrate 10, the gate structure GS4 is disposed above the well region 14D, and the gate oxide layer 36 is disposed between the gate structure GS4 and the well region 14D in the vertical direction D3. The drift region LD41 and the drift region LD42 are disposed in the well region 14D, and at least a part of the drift region LD41 and at least a part of the drift region LD42 are disposed at two opposite sides of the gate structure GS4, respectively. The doped region DR41 and the doped region DR42 are disposed in the drift region LD41 and the drift region LD42, respectively, and the spacer structure SP4 is disposed on the sidewall of the gate structure GS4 and the sidewall of the gate oxide layer 36. A thickness of the gate oxide layer 36 may be greater than the thickness of the second portion P12 of the gate oxide layer 30 illustrated in FIGS. 1 and 3-10 described above. A conductivity type of the drift region LD41, a conductivity type of the drift region LD42, a conductivity type of the doped region DR41, and a conductivity type of the doped region DR42 may be identical to one another, and a dopant concentration in the doped region DR41 and the doped region DR42 may be higher than that in the drift region LD41 and the drift region LD42. A conductivity type of the well region 14D may be complementary to the conductivity type of the drift region LD41, the drift region LD42, the doped region DR41, and the doped region DR42, and the conductivity type of the well region 14D may be identical to or complementary to the conductivity type of the deep well region 12. As shown in FIG. 13 and FIG. 1, in some embodiments, the structures and/or the materials compositions of the gate oxide layer 36, the gate structure GS4, and the spacer structure SP4 may be identical to or similar to the structures and/or the materials compositions of the gate oxide layer 30, the gate structure GS1, and the spacer structure SP1, respectively, and the gate oxide layer 36 in the high-voltage transistor 112 may have only a single thickness, but not limited thereto.

As shown in FIG. 12, FIG. 13, and FIG. 1, in some embodiments, the structures of the transistor T2 and the transistor T4 in the level-up shifting circuit may be identical to the structure of the high-voltage transistor 112. In other words, two high-voltage transistors 112 may be used as the transistor T2 and the transistor T4 in the level-up shifting circuit, the level-up shifting circuit may be regarded as a circuit including a second high-voltage transistor (such as the high-voltage transistor 112) accordingly, and the high-voltage transistor 112 includes a second well region (such as the well region 14D), a second gate structure (such as the gate structure GS4), a second gate oxide layer (such as the gate oxide layer 36), a third drift region (such as the drift region LD41), and a fourth drift region (such as the drift region LD42). When the high-voltage transistor 101 and the high-voltage transistor 112 are used as the transistor T1 and the transistor T2 in the level-up shifting circuit, respectively, the gate structure GS1, the doped region DR11, and the doped region DR12 of the high-voltage transistor 101 may be regarded as at least a part of the gate electrode G1, at least a part of the source/drain electrode SD11, and at least a part of the source/drain electrode SD12 in the transistor T1, respectively, and the gate structure GS4, the doped region DR41, and the doped region DR42 of the high-voltage transistor 112 may be regarded as at least a part of the gate electrode G2, at least a part of the source/drain electrode SD21, and at least a part of the source/drain electrode SD22 in the transistor T2, respectively. Therefore, the doped region DR11 of the high-voltage transistor 101 may be electrically connected with the gate structure GS4 of the high-voltage transistor 112, and the conductivity type of the well region 14D of the high-voltage transistor 112 may be complementary to the conductivity type of the well region 14A of the high-voltage transistor 101.

It is worth noting that the structure of the level-up shifting circuit including the high-voltage transistor in the present invention is not limited to the condition illustrated in FIG. 12, and the high-voltage transistor in the present invention may also be applied to other suitable level-up shifting circuits or circuits of other functions. Additionally, in some embodiments, the high-voltage transistors illustrated in FIGS. 1 and 3-10 may be used as the transistor T1 and the transistor T3 in the level-up shifting circuit, and the level-up shifting circuit may be regarded as a circuit including at least one of the transistors in FIGS. 1 and 3-10. The structures of the transistor T2, the transistor T4, the transistor T5, and the transistor T6 in the level-up shifting circuit may be identical to or similar to the structure of the high-voltage transistor 112 in FIG. 13, and the structures of the transistor T7, the transistor T8, the transistor T9, and the transistor T10 in the level-up shifting circuit may be identical to or similar to the structure of the transistor 110 in FIG. 10, but not limited thereto.

To summarize the above descriptions, according to the high-voltage transistor, the level-up shifting circuit, and the semiconductor device in the present invention, the gate oxide layer having different thicknesses at different portions may be used to lower the threshold voltage of the high-voltage transistor, and high voltage may still be applied to the gate structure for satisfying operation requirements of specific circuits by controlling the thickness ratio relationship between different portions of the gate oxide layer. Therefore, when the high-voltage transistor is used in the level-up shifting circuit, the condition that the high-voltage transistor cannot be driven when the driving voltage drops may be improved, and the operation performance of the level-up shifting circuit may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high-voltage transistor, comprising:
a well region disposed in a semiconductor substrate;
a gate structure disposed above the well region;
a gate oxide layer disposed between the gate structure and the well region in a vertical direction, wherein a first portion of the gate oxide layer is thicker than a second portion of the gate oxide layer, and a thickness of the second portion is greater than or equal to one eighth of a thickness of the first portion; and
a first drift region and a second drift region disposed in the well region, wherein at least a part of the first drift region and at least a part of the second drift region are located at two opposite sides of the gate structure in a horizontal direction, respectively, the first drift region is disposed adjacent to the first portion of the gate oxide layer, the second drift region is disposed adjacent to the second portion of the gate oxide layer, and a conductivity type of the first drift region is identical to a conductivity type of the second drift region.

2. The high-voltage transistor according to claim 1, further comprising:
a deep well region disposed in the semiconductor substrate and located under the well region in the vertical direction, wherein a conductivity type of the deep well region is complementary to a conductivity type of the well region, and the conductivity type of the deep well region is identical to the conductivity type of the first drift region and the conductivity type of the second drift region.

3. The high-voltage transistor according to claim 1, further comprising:
a deep well region disposed in the semiconductor substrate and located under the well region in the vertical direction, wherein a conductivity type of the deep well region is identical to a conductivity type of the well region, and the conductivity type of the deep well region is complementary to the conductivity type of the first drift region and the conductivity type of the second drift region.

4. The high-voltage transistor according to claim 1, further comprising:
a first doped region disposed in the first drift region; and
a second doped region disposed in the second drift region, wherein the first doped region and the second doped region are located at the two opposite sides of the gate structure in the horizontal direction, respectively, and a conductivity type of the first doped region and a conductivity type of the second doped region are identical to the conductivity type of the first drift region and the conductivity type of the second drift region.

5. The high-voltage transistor according to claim 1, wherein the thickness of the second portion of the gate oxide layer is greater than or equal to a quarter of the thickness of the first portion of the gate oxide layer.

6. The high-voltage transistor according to claim 1, wherein a length of the first portion of the gate oxide layer in the horizontal direction is less than a length of the second portion of the gate oxide layer in the horizontal direction.

7. The high-voltage transistor according to claim 1, wherein a part of the first drift region is disposed under the gate structure in the vertical direction, and the second drift region is not disposed under the gate structure in the vertical direction.

8. The high-voltage transistor according to claim 1, wherein a part of the second drift region is disposed under the gate structure in the vertical direction, and the first drift region is not disposed under the gate structure in the vertical direction.

9. The high-voltage transistor according to claim 1, further comprising:
a third drift region disposed in the well region and located under the first drift region, wherein a bottom of the third drift region is lower than a bottom of the second drift region.

10. The high-voltage transistor according to claim 1, wherein at least a part of the gate oxide layer is disposed in the semiconductor substrate, and a bottom surface of the first portion of the gate oxide layer and a bottom surface of the second portion of the gate oxide layer are lower than a top surface of the semiconductor substrate in the vertical direction.

11. A level-up shifting circuit, comprising:
a first high-voltage transistor, wherein the first high-voltage transistor comprises:
a first well region disposed in a semiconductor substrate;
a first gate structure disposed above the first well region;
a first gate oxide layer disposed between the first gate structure and the first well region in a vertical direction, wherein a first portion of the first gate oxide layer is thicker than a second portion of the first gate oxide layer, and a thickness of the second portion is greater than or equal to one eighth of a thickness of the first portion; and
a first drift region and a second drift region disposed in the first well region, wherein at least a part of the first drift region and at least a part of the second drift region are located at two opposite sides of the first gate structure in a horizontal direction, respectively, the first drift region is disposed adjacent to the first portion of the first gate oxide layer, the second drift region is disposed adjacent to the second portion of the first gate oxide layer, and a conductivity type of the first drift region is identical to a conductivity type of the second drift region.

12. The level-up shifting circuit according to claim 11, further comprising:
a second high-voltage transistor, wherein the second high-voltage transistor comprises:
a second well region disposed in the semiconductor substrate;
a second gate structure disposed above the second well region; and
a second gate oxide layer disposed between the second gate structure and the second well region in the vertical direction, wherein the first high-voltage transistor further comprises a first doped region disposed in the first drift region, and the first doped region is electrically connected with the second gate structure of the second high-voltage transistor.

13. The level-up shifting circuit according to claim 12, wherein the first high-voltage transistor further comprises a second doped region disposed in the second drift region, the first doped region and the second doped region are located at the two opposite sides of the first gate structure in the horizontal direction, respectively, and a conductivity type of the first doped region and a conductivity type of the second doped region are identical to the conductivity type of the first drift region and the conductivity type of the second drift region.

14. The level-up shifting circuit according to claim 12, wherein the second high-voltage transistor further comprises:
a third drift region and a fourth drift region disposed in the second well region, wherein at least a part of the third drift region and at least a part of the fourth drift region are located at two opposite sides of the second gate structure, respectively, and a conductivity type of the third drift region is identical to a conductivity type of the fourth drift region.

15. The level-up shifting circuit according to claim 14, wherein a conductivity type of the second well region is complementary to the conductivity type of the third drift region and the conductivity type of the fourth drift region, and the conductivity type of the second well region is complementary to the conductivity type of the first well region.

16. The level-up shifting circuit according to claim 11, wherein a conductivity type of the first well region is complementary to the conductivity type of the first drift region and the conductivity type of the second drift region.

17. The level-up shifting circuit according to claim 11, wherein a length of the first portion of the first gate oxide layer in the horizontal direction is less than a length of the second portion of the first gate oxide layer in the horizontal direction.

18. The level-up shifting circuit according to claim 11, wherein a part of the first drift region is disposed under the first gate structure in the vertical direction, and the second drift region is not disposed under the first gate structure in the vertical direction.

19. The level-up shifting circuit according to claim 11, wherein a part of the second drift region is disposed under the first gate structure in the vertical direction, and the first drift region is not disposed under the first gate structure in the vertical direction.

20. The level-up shifting circuit according to claim 11, wherein at least a part of the first gate oxide layer is disposed in the semiconductor substrate, and a bottom surface of the first portion of the first gate oxide layer and a bottom surface of the second portion of the first gate oxide layer are lower than a top surface of the semiconductor substrate in the vertical direction.

21. A semiconductor device, comprising:
a first transistor, wherein the first transistor comprises:
a first well region disposed in a semiconductor substrate;
a first gate structure disposed above the first well region; and
a first gate oxide layer disposed between the first gate structure and the first well region in a vertical direction, wherein the first gate oxide layer comprises:
a first portion having a first thickness; and
a second portion having a second thickness, wherein the first thickness is greater than the second thickness; and
a second transistor, wherein the second transistor comprises:
a second well region disposed in the semiconductor substrate;
a second gate structure disposed above the second well region; and
a second gate oxide layer disposed between the second gate structure and the second well region in the vertical direction, wherein the second gate oxide layer has a third thickness, and the second thickness is greater than the third thickness.

22. The semiconductor device according to claim 21, wherein the first transistor is a high-voltage transistor, and the second transistor is a low-voltage transistor.

23. The semiconductor device according to claim 21, wherein the first transistor further comprises a drift region disposed in the first well region, the second transistor further comprises a lightly doped region disposed in the second well region, and a depth of the drift region is greater than a depth of the lightly doped region.

24. The semiconductor device according to claim 21, wherein a structure the first gate structure is different from a structure of the second gate structure or a material composition of the first gate structure is different from a material composition of the second gate structure.

25. The semiconductor device according to claim 21, wherein the first gate structure and the second gate structure comprise a metallic electrically conductive material.

26. The semiconductor device according to claim 21, wherein the first gate structure and the second gate structure comprise a non-metallic electrically conductive material.

27. The semiconductor device according to claim 21, wherein the first gate structure comprises a non-metallic electrically conductive material, and the second gate structure comprises a metallic electrically conductive material.
